(19) United States
(12) Patent Application Publication
(10) Pub. No.: US 2024/0107832 A1
(43) Pub. Date: Mar. 28, 2024

(54) DISPLAY DEVICE

(71) Applicant: Samsung Display Co., LTD., Yongin-si (KR)

(72) Inventors: Youngmin CHO, Yongin-si (KR); Hongam KIM, Yongin-si (KR)

(21) Appl. No.: 18/212,094

(22) Filed: Jun. 20, 2023

(30) Foreign Application Priority Data
Sep. 27, 2022 (KR) 10-2022-0122077

(51) Int. Cl. H10K 59/131; H01L 23/00

(52) U.S. Cl. CPC H10K 59/131; H01L 24/05; H01L 24/06; H01L 24/32; H10K 59/35

(57) ABSTRACT

A display device includes a display panel, in which a display region and a non-display region are defined, where the display panel includes a base layer including a front surface and a rear surface opposing the front surface, a circuit layer including pixel circuits disposed on the front surface, where each pixel circuit includes semiconductor patterns and conductive patterns, a light emitting device layer including light emitting devices connected to relevant pixel circuits of the pixel circuits, and display pads connected to the relevant pixel circuits and exposed to the rear surface overlapping the display region, and a circuit board disposed on the rear surface overlapping the display region and including substrate pads connected to the display pads. A first display pad and a second display pad, which are adjacent to each other, of the display pads overlap pixels with a substantially same overlapping region as each other.

This application claims priority to Korean Patent Application No 10-2022-0122077, filed on Sep. 27, 2022, and all the benefits accruing therefrom under 35 U.S.C. § 119, the content of which in its entirety is incorporated by reference.

### BACKGROUND

### 1. Field

Embodiments of the disclosure described herein relate to a display device, and more particularly, relate to a display device including a circuit board bonded to a rear surface of a display panel.

### 2. Description of the Related Art

Electronic devices, such as a smartphone, a tablet personal computer (PC), a notebook computer, a navigation system for a vehicle, and a smart television, have been developed. The electronic devices typically include a display device to provide information.

To improve the visibility and aesthetic appeal of the display device, a bezel-less display device having a reduced bezel region has been actively developed.

### SUMMARY

Embodiments of the disclosure provide a display device having a reduced bezel region.

According to an embodiment, a display device includes a display panel, in which a display region and a non-display region are defined, where the display panel includes a base layer including a front surface and a rear surface opposing the front surface, a circuit layer including pixel circuits disposed on the front surface, where each pixel circuit includes semiconductor patterns and conductive patterns, a light emitting device layer including light emitting devices connected to relevant pixel circuits of the pixel circuits, and display pads connected to the relevant pixel circuits and exposed to the rear surface overlapping the display region, and a circuit board disposed on the rear surface overlapping the display region and including substrate pads connected to the display pads. In such an embodiment, a first display pad and a second display pad, which are adjacent to each other, of the display pads overlap relevant semiconductor patterns of the semiconductor patterns and relevant conductive patterns of the conductive patterns with a substantially same overlapping region as each other.

In an embodiment, regions, in which the first display pad overlaps the pixel circuits, may be symmetrical with regions in which the second display pad overlaps the pixel circuits.

In an embodiment, a portion of the first display pad may overlap a portion of a first pixel circuit of the pixel circuits, and a portion of the second display pad may be overlap another portion of the first pixel circuit.

In an embodiment, another portion of the first display pad may overlap a portion of a second pixel circuit of the pixel circuits, and another portion of the second display pad may overlap a portion of a third pixel circuit of the pixel circuits.

In an embodiment, the light emitting device connected to the first pixel circuit may emit first color light, the light emitting device connected to the second pixel circuit may emit second color light different from the first color light, and the light emitting device connected to the third pixel circuit may emit the second color light.

In an embodiment, the first display pad and the second display pad may extend in a first direction and may be spaced apart from each other in a second direction crossing the first direction, the first display pad may overlap a first pixel circuit and a second pixel circuit, which are spaced apart from each other in the first direction, of the pixel circuits, and the second display pad may overlap a third pixel circuit, which is spaced apart from the first pixel circuit in the second direction, of the pixel circuits, and a fourth pixel circuit, which is spaced apart from the second pixel circuit in the second direction and is spaced apart from the third pixel circuit in the first direction.

In an embodiment, the light emitting device connected to the first pixel circuit and the light emitting device connected to the fourth pixel circuit may emit first color light, and the light emitting device connected to the second pixel circuit and the light emitting device connected to the third pixel circuit may emit second color light different from the first color light.

In an embodiment, the first display pad and the second display pad may define a pad group, the pad group may be provided in plural, and a plurality of pad groups may be spaced apart from each other in one direction.

In an embodiment, the first display pad and the second display pad may have a same area as each other.

In an embodiment, the first display pad and the second display pad may have a same shape as each other.

In an embodiment, the circuit layer may include a plurality of insulating layers, and the semiconductor patterns and the conductive patterns may be interposed between the insulating layers.

In an embodiment, the display device may further include a lower film interposed between the display panel and the circuit board, and a portion of the circuit board may be disposed on a rear surface of the lower film.

In an embodiment, the display pads and the substrate pads may be connected to each other through an anisotropic conductive film.

In an embodiment, the display device may further include an input sensor directly disposed on the display panel, and including at least one conductive layer and at least one sensing insulating layer.

In an embodiment, the display device may further include an anti-reflective layer disposed on the input sensor.

In an embodiment, the display device may further include a window disposed on the anti-reflective layer, and the window may include a base substrate, and a bezel pattern disposed on a bottom surface of the base substrate and overlapping the non-display region.

According to an embodiment, a display device includes a base layer including a front surface, on which a display region and a non-display region are defined, and a rear surface opposing the front surface, a pixel including a pixel circuit including semiconductor patterns and conductive patterns and a light emitting device connected to the pixel circuit, disposed on the front surface, a display pad connected to the pixel circuit and exposed to the rear surface overlapping the display region, and a circuit board facing the rear surface overlapping the display region and including substrate pads. In such an embodiment, the display pad is provided in plural, each of the substrate pads is connected to a relevant display pad of display pads, and a first display pad and a second display pad, which are adjacent to each other, of the display pads overlap the pixel circuits with a substantially same overlapping area as each other.

In an embodiment, the pixel may include each of at least one transistor including an active pattern, which is defined by a portion of the semiconductor patterns, and a gate overlapping the active pattern, and the at least one transistor may be connected to the light emitting device.

In an embodiment, the display device may further include a signal line connected to the pixel and defined by a portion of the conductive patterns, and the signal line may include scan lines, data lines, light emitting lines, control lines, and a power line.

In an embodiment, Regions, in which the first display pad overlaps the pixel circuits, may be symmetrical with regions in which the second display pad overlaps the pixel circuits.

### BRIEF DESCRIPTION OF THE DRAWINGS

The above and other features of the disclosure will become apparent by describing in detail embodiments thereof with reference to the accompanying drawings, in which:

FIG. 1 is a perspective view of an electronic device according to an embodiment of the disclosure;

FIG. 2 is an exploded perspective view of an electronic device according to an embodiment of the disclosure;

FIG. 3 is a cross-sectional view of an electronic device according to an embodiment of the disclosure;

FIG. 4 is a cross-sectional view of a display module according to an embodiment of the disclosure;

FIG. 5A is a plan view of a display panel according to an embodiment of the disclosure;

FIG. 5B is an enlarged plan view of a display region of FIG. 5A;

FIG. 6 is a cross-sectional view of a display module according to an embodiment of the disclosure;

FIG. 7A is a plan view of pixel circuits according to an embodiment of the disclosure;

FIG. 7B is a plan view illustrating the arrangement relationship between pixel circuits and pads, according to an embodiment of the disclosure;

FIG. 8 is a plan view illustrating the arrangement relationship between pixel circuits and pads, according to an embodiment of the disclosure; and

FIG. 9 is a plan view illustrating the arrangement relationship between pixel circuits and pads, according to an embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the specification, the expression that a first component (or area, layer, part, portion, etc.) is “on”, “connected with”, or “coupled to” a second component means that the first component is directly on, connected with, or coupled to the second component or means that a third component is disposed therebetween.

The same reference numeral refers to the same component. In addition, in drawings, thicknesses, proportions, and dimensions of components may be exaggerated to describe the technical features effectively.

Although the terms “first”, “second”, etc. may be used to describe various components, the components should not be construed as being limited by the terms. The terms are only used to distinguish one component from another component. For example, without departing from the scope and spirit of the disclosure, a first component may be referred to as a second component, and similarly, the second component may be referred to as the first component.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

In addition, the terms “under”, “below”, “on”, “above”, etc. are used to describe the correlation of components illustrated in drawings. The terms that are relative in concept are described based on a direction shown in drawings.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical terms and scientific terms) used in the specification have the same meaning as commonly understood by one skilled in the art to which the disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described with reference to the accompanying drawings.

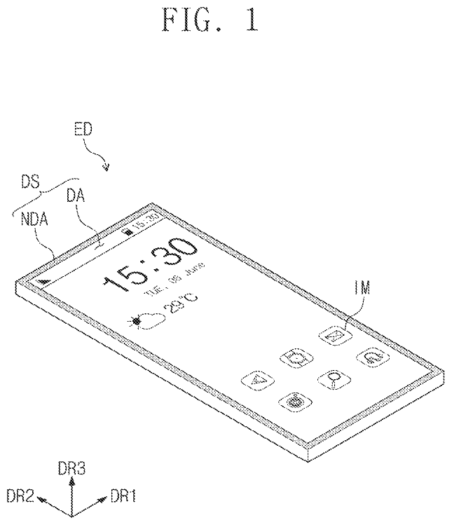

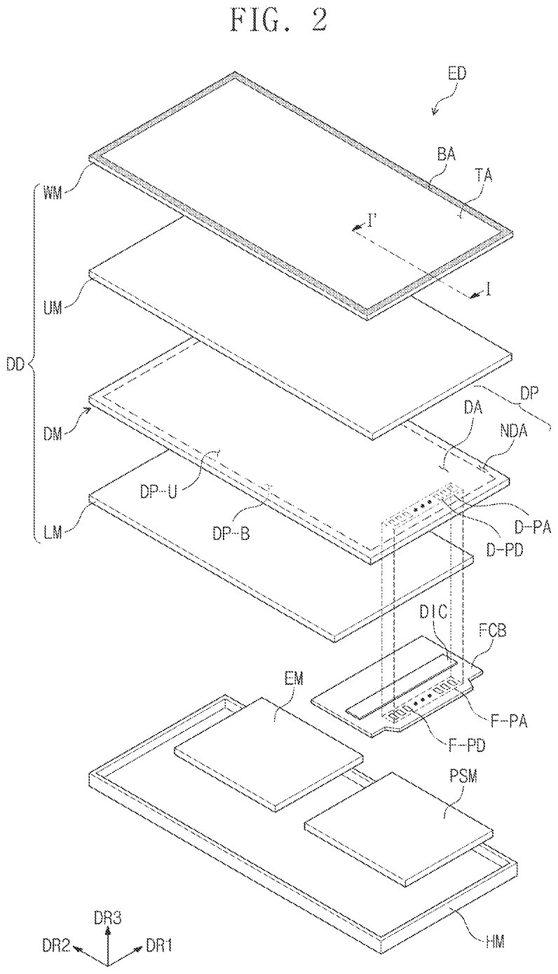

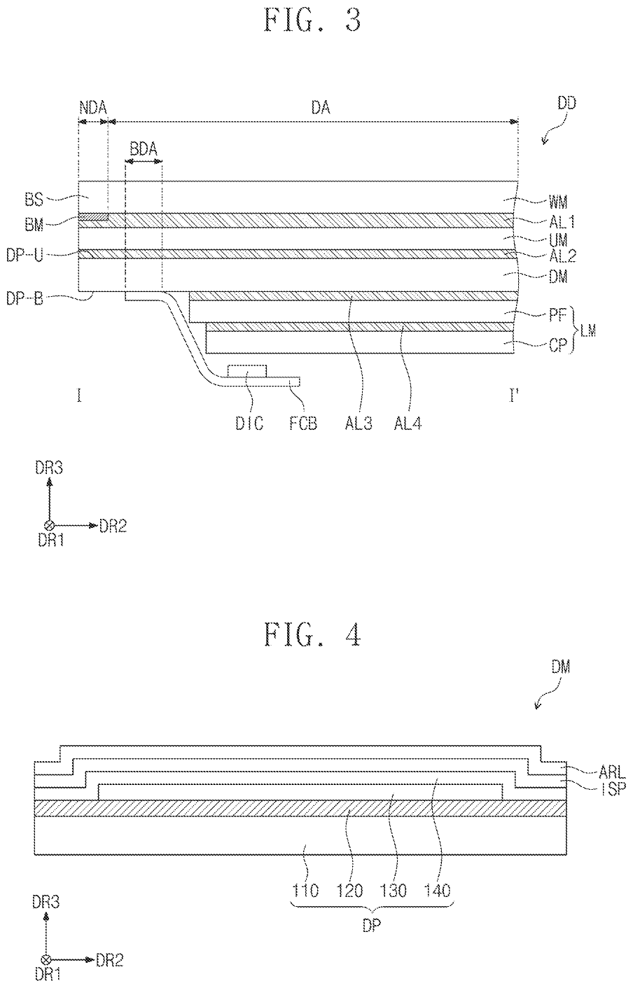

FIG. 1 is a perspective view of an electronic device according to an embodiment of the disclosure. FIG. 2 is an exploded perspective view of an electronic device according to an embodiment of the disclosure. FIG. 3 is a cross-sectional view of an electronic device according to an embodiment of the disclosure.

Referring to FIGS. 1 and 2, an electronic device ED according to an embodiment of the disclosure may include a display surface DS on a plane defined by a first direction DR1 and a second direction DR2 crossing the first direction DR1. The electronic device ED may provide an image IM to a user through the display surface DS.

The display surface DS may include a display region DA and a non-display region NDA around the display region DA. The display region DA may display the image IM, and the non-display region NDA may not display the image IM. The non-display region NDA may surround the display region DA. However, the disclosure is not limited thereto. In an alternative embodiment, for example, the display region DA and the non-display region NDA may be variously modified.

Hereinafter, a direction substantially perpendicular to a plane defined by the first direction DR1 and the second direction DR2 is defined as a third direction DR3. The third direction DR3 may be a thickness direction of the electronic device ED. The third direction DR3 may serve as a basis for distinguishing between a front surface and a rear surface of members. In the disclosure, the wording “in a plan view” may refer to the state when viewed in the third direction DR3.

According to an embodiment, the electronic device ED may be a foldable electronic device to be folded about a folding axis. The folding axis may be parallel to the first direction DR1 or the second direction DR2, and a folding region may be defined in a portion of the display region DA. The electronic device ED may be in an in-folding state in which display regions DA are folded to face each other, or in an out-folding state in which the display regions DA are folded to opposite to each other.

The electronic device ED may include a display device DD, an electronic module EM, a power supply module PSM, and a housing HM. FIG. 2 schematically illustrates an embodiment of the electronic device ED, and the electronic device ED may further include a mechanism structure to control an operation (e.g., folding or rolling) of the display device DD.

The display device DD generates an image and detects an external input. The display device DD includes a window WM, an upper member UM, a display module DM, a lower member LM, a circuit board FCB, and a driving chip DIC. The upper member UM includes a member disposed above the display module DM, and the lower member LM includes a member disposed below the display module DM.

The window WM provides a front surface of the electronic device ED. The window WM includes a transmission region TA and a bezel region BA. The display region DA and the non-display region NDA of the display surface DS illustrated in FIG. 1 are defined by the transmission region TA and the bezel region BA. The transmission region TA is a region through which an image passes, and the bezel region BA is a region for covering a structure/member disposed below the window WM. The transmission region TA has a higher light transmittance than the bezel region BA.

The display module DM may include a display panel DP. Although FIG. 2 illustrates only the display panel DP of a stack structure of the display module DM, the display module DM may substantially include not only the display panel DP but also a plurality of components disposed above the display panel DP. The details of the stack structure of the display modules DM will be described later.

The display panel DP may be any one of an organic light emitting display panel, an inorganic light emitting display panel, an organic-inorganic light emitting display panel, a quantum dot display panel, a micro-light emitting diode (LED) display panel, and a nano-LED display panel. The display panel DP may include a front surface DP-U on which an image is provided and a rear surface DP-B opposite to the front surface DP-U. The front surface DP-U includes a display region DA and a non-display region NDA which correspond to the display region NDA and the non-display region NDA illustrated in FIG. 1, respectively. In the disclosure, the wording “a region/part corresponds to a region/part” refers to that the region/part overlap the region/part”, and does not refer to that the region/part has an area the same as an area of the region/part.

According to an embodiment of the disclosure, the display pad region D-PA of the display panel DP is disposed at one side of the rear surface DP-B overlapping the display region NDA. The display pads D-PD may be disposed in the display pad region D-PA. The display pad region D-PA may be a part electrically bonded to the circuit board FCB to be described later.

The upper member UM may include a protective film or an optical film. The optical film may include a polarizer and a retarder to reduce reflection of external light. The lower member LM may include a protective film to protect the display panel DP, and a support member to support the display panel DP, or a digitizer.

The circuit board FCB is disposed below the display panel DP. The circuit board FCB may be bonded to the rear surface of the display panel DP, and may electrically connect the display panel DP to the main circuit board which is not illustrated. The circuit board FCB includes at least one insulating layer and at least one conductive layer. The conductive layer may include a plurality of signal lines. The circuit board FCB may include a substrate pad area F-PA bonded to the display pad area D-PA. Substrate pads F-PD bonded to the display pads D-PD, respectively, may be disposed in the substrate pad region F-PA. According to an embodiment of the disclosure, the substrate pads F-PD and the display pads D-PD may be bonded to the rear surface DP-B overlapping the display region NDA.

The driving chip DIC may be mounted on the circuit board FCB. The driving chip DIC may include a driving circuit to drive a pixel of the display panel DP, for example, a data driving circuit. Although FIG. 2 illustrates an embodiment having a structure in which the driving chip DIC is mounted on the circuit board FCB, the disclosure is not limited thereto. In an alternative embodiment, for example, the driving chip DIC may be mounted on the display panel DP or the main circuit board.

The electronic module EM may include a control module, a wireless communication module, an image input module, a sound input module, a sound output module, a memory, or an external interface module. The electronic module EM may include a main circuit board, and the modules may be mounted on the main circuit board or may be electrically connected to the main circuit board through the flexible circuit board. The electronic module EM is electrically connected to the power supply module PSM.

Although not illustrated separately, the electronic device ED may further include an electronic optical module. The electronic optical module may be an electronic component to output or receive an optical signal. The electronic optical module may include a camera module and/or a proximity sensor. The camera module may photograph an external image through a partial region of the display panel DP.

The housing HM is particularly coupled to the window WM to receive other components included in the electronic device ED. Although FIG. 2 shows an embodiment where the housing HM has an integral shape, the disclosure is not limited thereto. Alternatively, the housing HM may include a plurality of parts (e.g., a side edge part and a bottom part) coupled to each other.

FIG. 3 additionally illustrates adhesive layers AL1 to AL4 not illustrated in FIG. 2.

Referring to FIG. 3, in an embodiment, the window WM may include a base substrate BS and a bezel pattern BM disposed on a bottom surface of the base substrate BS. The base substrate BS may include a synthetic resin film or a glass substrate. The base substrate BS may have a multilayer structure. The base substrate BS may include a thin film glass substrate, a protective film disposed on a thin film glass substrate, and an adhesive layer connecting or attaching the thin film glass substrate to the protective film.

The bezel pattern BM, which serves as a colored light blocking film, may be formed through a coating scheme. The bezel pattern BM may include a base material and a dye or pigment mixed with the base material. The bezel pattern BM may overlap the non-display region NDA and define the bezel region BA of the window WM illustrated in FIG. 2. The bezel pattern BM may be disposed on the bottom surface of the base substrate BS. In an embodiment where the base substrate BS has a multilayer structure, the bezel pattern BM may be interposed between interfaces defined by a plurality of layers. In an embodiment, for example, the bezel pattern BM may be interposed between a thin film glass substrate and a protective film. Although not illustrated separately, the window WM may further include at least one selected from a hard coating layer, an anti-fingerprint layer, and an anti-reflective layer on a top surface of the base substrate BS.

The upper member UM may include an upper film that absorbs an external impact applied to the front surface of the display device DD. The upper film may include a synthetic resin film. The synthetic resin film may include polyimide, polycarbonate, poly amide, triacetylcellulose, polymethylmethacrylate, or polyethylene terephthalate.

According to an embodiment of the disclosure, the display module DM may include a color filter, which serves as an anti-reflective member and used instead of the polarizing film. Accordingly, the strength of an impact on a front surface of the display device DD may be reduced. The upper film may compensate for the reduced impact strength by applying a color filter.

The window WM and the upper member UM may be coupled to each other by a first adhesive layer AL1. The first adhesive layer AL1 may be a pressure sensitive adhesive film (PSA) or an optically clear adhesive member (OCA). The adhesive layers described below may also include a same adhesive material as the first adhesive layer AL1.

The upper member UM and the display module DM may be coupled to each other by a second adhesive layer AL2. The second adhesive layer AL2 may be disposed on the front surface DP-U of the display panel DP (see FIG. 2). The display module DM and the lower member LM may be coupled to each other through a third adhesive layer AL3. The third adhesive layer AL3 may be disposed on the rear surface DP-B of the display panel DP (see FIG. 2).

The lower member LM may include a lower film PF and a cover panel CP. The lower film PF may protect a lower portion of the display module DM. The lower film PF may include a flexible synthetic resin film. In an embodiment, for example, the lower film PF may include, but is not limited to, polyethylene terephthalate or polyimide.

The lower film PF may be spaced apart from the bonding region BDA for bonding the display panel DP (see FIG. 2) to the circuit board FCB. Accordingly, the lower film PF may have a smaller area than the area of the display module DM. In an embodiment, for example, the lower film PF may overlap only the display region DA. However, the disclosure is not limited thereto, and alternatively, the lower film PF may have substantially the same area as the display module DM. In such an embodiment, the lower film PF may be provided with an open region for exposing the rear surface DP-B of the display panel DP, which overlaps the bonding region BDA.

The lower film PF and the cover panel CP may be bonded to each other by the fourth adhesive layer AL4. The cover panel CP may increase resistance to compressive force generated from external pressure. Accordingly, the cover panel CP may serve to prevent deformation of the display panel DP. The cover panel CP may include a flexible plastic material such as polyimide or polyethylene terephthalate. In addition, the cover panel CP may be a colored film having a low light transmittance. The cover panel CP may absorb light incident from the outside. In an embodiment, for example, the cover panel CP may be a black synthetic resin film. When viewing the display device DD from the upper portion of the window WM, the components arranged on the lower portion of the cover panel CP may not be viewed by the user.

In an embodiment, one side of the circuit board FCB may be contact with the rear surface DP-B of the display panel DP (refer to FIG. 2) in the bonding region BDA, and an opposite side of the circuit board FCB may face the cover panel CP. In such an embodiment, a part between the one side and the opposite side of the circuit board FCB is bent to cover a side surface of the lower member LM, when viewed in the second direction DR2.

The driving chip DIC may be disposed on the opposite side of the circuit board FCB to face the cover panel CP. According to an embodiment, a groove part may be defined in the cover panel CP to insert at least a portion of the driving chip DIC therein. The groove part may allow a crooked portion formed by the thickness of the driving chip DIC to be inserted therein.

A support plate may be disposed below the cover panel CP. The support plate may include a metal material having a high strength. The support plate may include a reinforced fiber composite. The support plate may include a reinforced fiber disposed inside the matrix part. The reinforced fiber may be carbon fiber or glass fiber. The matrix part may include a polymer resin. The matrix part may include a thermoplastic resin. In an embodiment, for example, the matrix part may include a polyamide-based resin or a polypropylene-based resin. In an embodiment, for example, the reinforced fiber composite may be a carbon fiber reinforced plastic (CFRP) or glass fiber reinforced plastic (GFRP).

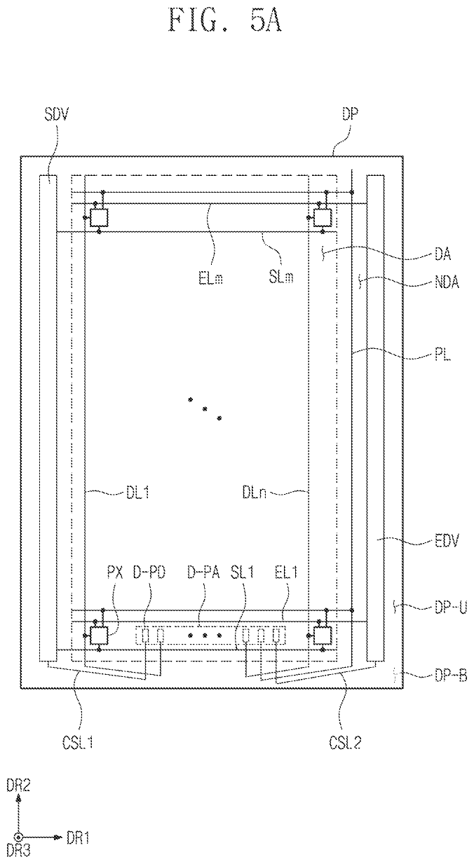

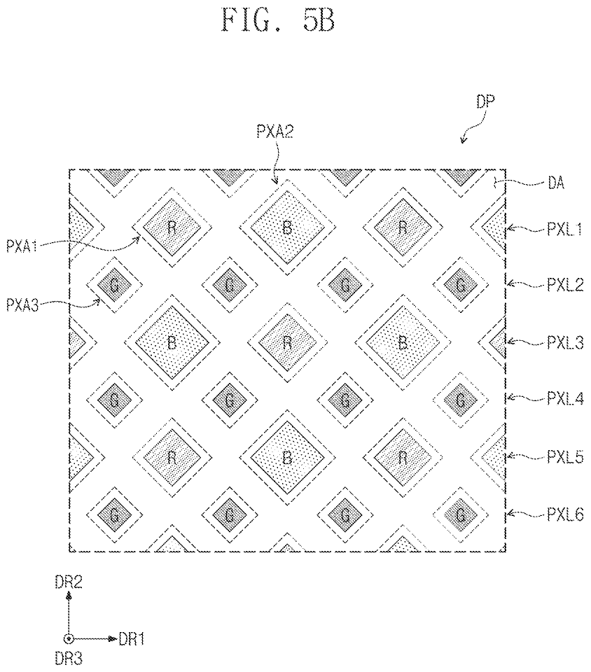

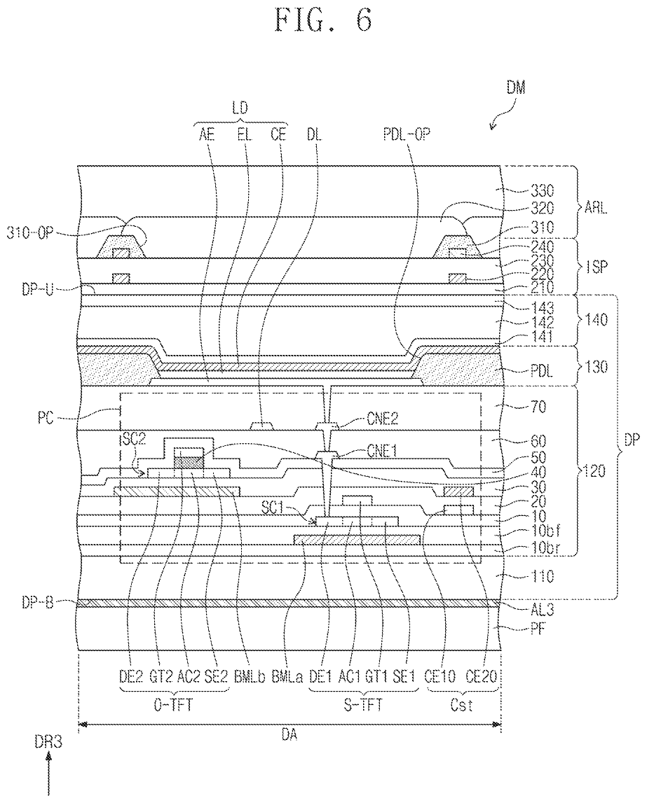

FIG. 4 is a cross-sectional view of a display module, according to an embodiment of the disclosure. FIG. 5A is a plan view of a display panel, according to an embodiment of the disclosure. FIG. 5B is an enlarged plan view of a display region of FIG. 5A. FIG. 6 is a cross-sectional view of a display module, according to an embodiment of the disclosure.

Referring to FIG. 4, an embodiment of the display module DM may include a display panel DP, an input sensor ISP, and an anti-reflective layer ARL. The display panel DP may include a base layer 110, a circuit layer 120, a light emitting device layer 130, and an encapsulation layer 140.

The base layer 110 may provide a base surface for disposing or supporting the circuit layer 120. The base layer 110 may be a flexible substrate allowing bending, folding, or rolling. The base layer 110 may be a glass substrate, a metal substrate, or a polymer substrate. However, the embodiment of the disclosure is not limited thereto, and alternatively, the base layer 110 may be an inorganic layer, an organic layer, or a composite material layer.

The base layer 110 may have a multilayer structure. In an embodiment, for example, the base layer 110 may include a first synthetic resin layer, a second synthetic resin layer, and inorganic layers disposed therebetween. Each of the first and second synthetic resin layers may include a polyimide-based resin, but is not particularly limited thereto. The display pads D-PD described with reference to FIG. 2 may be exposed to the outside from the first synthetic resin layer disposed at the lowest side.

The circuit layer 120 may be disposed on the base layer 110. The circuit layer 120 may include insulating layers, semiconductor patterns, and conductive patterns. Some of the conductive patterns may define “signal lines”. According to an embodiment of the disclosure, the signal lines may include a plurality of scan lines SL1 to SLm, a plurality of data lines DL1 to DLn, a plurality of light emitting lines EL1 to ELm, first and second control lines CSL1 and CSL2, and power lines PL to be described with reference to FIG. 5A.

The display pads D-PD may be connected to any one of semiconductor patterns and conductive patterns included in the circuit layer 120.

The light emitting device layer 130 may be disposed on the circuit layer 120. The light emitting device layer 130 may include a light emitting device. In an embodiment, for example, a light emitting device may include an organic light emitting material, an inorganic light emitting material, an organic-inorganic light emitting material, a quantum dot, a quantum rod, a micro-LED, or a nano-LED.

The encapsulation layer 140 may be disposed on the light emitting device layer 130. The encapsulation layer 140 may protect the light emitting device layer 130 from foreign substances such as moisture, oxygen, and dust particles. The encapsulation layer 140 may include at least one inorganic layer. The encapsulation layer 140 may include a stack structure of an inorganic layer/an organic layer/an inorganic layer.

The input sensor ISP may be directly disposed or formed on the display panel DP. The input sensor ISP may detect a user input in a capacitive manner. In an embodiment, the display panel DP and the input sensor ISP may be formed through successive processes or processes subsequent one to another. Here, the wording “directly disposed” may refer to that a third component is not interposed between the input sensor ISP and the display panel DP. In other words, a separate adhesive layer may not be interposed between the input sensor ISP and the display panel DP.

The anti-reflective layer ARL may be directly disposed on the input sensor ISP. The anti-reflective layer ARL may reduce the reflectance of external light to the anti-reflective layer AR1 incident from the outside of the display device DD. The anti-reflective layer ARL may include color filters. The color filters may have a specific array. In an embodiment, for example, the color filters may be arranged based on light emitting colors of pixels included in the display panel DP. In addition, the anti-reflective layer ARL may further include a black matrix adjacent to the color filters. According to an embodiment of the disclosure, the anti-reflective layer ARL may be replaced with a polarization film. The polarizing film may be coupled to the input sensor ISP through an adhesive layer.

Referring to FIG. 5A, the display surface DP may include a display region DA and a non-display region NDA around the display region DA. A plurality of pixels PX may be disposed in the display region DA. The pixel PX may be defined to include a pixel circuit PC (see FIG. 6) and a light emitting device LD (see FIG. 6). The scan driver SDV, the data driver, and the light emitting driver EDV may be disposed in the non-display region NDA. The data driver may be a partial circuit constituting the driving chip DIC illustrated in FIG. 3.

The display panel DP may include a plurality of pixels PX, a plurality of scan lines SL1 to SLm, a plurality of data lines DL1 to DLn, a plurality of light emitting lines EL1 to ELm, first and second control lines CSL1, CSL2, and power lines PL. m and n are natural numbers. The pixels PX may be connected to scan lines SL1 to SLm, data lines DL1 to DLn, and light emitting lines EL1 to ELm. A plurality of scan lines SL1 to SLm, a plurality of data lines DL1 to DLn, a plurality of light emitting lines EL1 to ELm, the first and second control lines CSL1 and CSL2, and the power line PL may be defined as a “signal line”.

The scan lines SL1 to SLm may extend in the second direction DR2 to be connected to the scan driver SDV. The light emitting lines EL1 to ELm may extend in the first direction DR1 to be connected to the light emitting driver EDV.

The power line PL may include a portion extending in the second direction DR2 and a portion extending in the first direction DR1. A portion extending in the first direction DR1 and a portion extending in the second direction DR2 may be disposed in different layers from each other. The power line PL may provide a first voltage to the pixels PX.

The data lines DL1 to DLn extend in the second direction DR2, and an end portion of each of the data lines DL1 to DLn is disposed in the pad region PA. The data lines DL1 to DLn may be electrically connected to the driving chip DIC. The first control line CSL1 is connected to the scan driver SDV, and an end of the control line CSL1 is disposed in the pad area PA. The second control line CSL2 is connected to the light emitting driver EDV, and an end of the second control line CSL2 is disposed in the pad region PA.

According to an embodiment of the disclosure, scan lines SL1 to SLm, data lines DL1 to DLn, light emitting lines EL1 to ELm, first and second control lines CSL1 and CSL2, and a power line PL may be defined by “conductive patterns” included in the circuit layer 120 described with respect to FIG. 4. At least one of the scan lines SL1 to SLm, the data lines DL1 to DLn, the light emitting lines EL1 to ELm, the first and second control lines CSL1 and CSL2, and the power line PL may be insulated by conductive layers included in the circuit layer 120 (see FIG. 4) and may be disposed in mutually different layers.

The data lines DL1 to DLn, the light emitting lines EL1 to ELm, the first and second control lines CSL1 and CSL2, and the power line PL may be connected to relevant display pads D-DP. The data lines DL1 to DLn, the light emitting lines EL1 to ELm, the first and second control lines CSL1 and CSL2, and the power line PL may be connected to the display pads D-DP disposed on the rear surface DP-B of the display panel DP through the insulating layers included in the circuit layer 120 (see FIG. 4).

FIG. 5B illustrates pixel areas PXA1, PXA2, and PXA3 disposed in the display region DA of the display panel DP. Each of the pixel regions PXA1, PXA2, and PXA3 may be defined as a region for providing light generated from the pixel PX.

According to an embodiment, the display region DA may include the pixel regions PXA1, PXA2, and PXA3 for providing light in different colors from each other. FIG. 5B illustrates first to sixth pixel rows PXL1 to PXL6 among a plurality of pixel rows, for convenience of illustration. One pixel row may be defined as a row of pixels including pixel regions arranged in the first direction DR1, and the first to seventh pixel rows PXL1 to PXL6 may be spaced apart from each other in the second direction DR2.

The first pixel region PXA1 to provide first color light, and the second pixel region PXA2 to provide second color light different from the first color light may be alternately disposed in the first direction DR1 in odd-numbered pixel rows PXL1, PXL3, and PXL5. The first color light may be red light, and the second color light may be blue light. The alternately-arranging form of the first pixel region PXA1 and the second pixel region PXA2 in the first pixel row PXL1 may be the same as the alternately-arranging form of the first pixel region PXA1 and the second pixel region PXA2 in the fifth pixel row PXL5.

The first pixel region PXA1 in the third pixel row PXL3 may be spaced apart in the second direction DR2 from the second pixel region PXA2 in the first pixel row PXL1 and may be spaced apart, in an oblique direction of the first direction DR1 and the second direction DR2, from the first pixel area PXA1 in the first pixel row PXL1.

The third pixel regions PXA3 for providing the third color light different from the first color light and the second color light may be spaced apart from each other in the first direction DR1, in even-numbered pixel rows PXL2, PXL4, and PXL6.

Referring to FIG. 6, the pixel circuit PC for driving the light emitting device LD according to an embodiment of the disclosure may include a plurality of transistors and the conductive patterns described above. Although FIG. 6 illustrates a silicon transistor S-TFT and an oxide transistor O-TFT included in the pixel circuit PC, this is provided only for the illustrative purpose, the pixel circuit PC may include only one of the silicon transistor S-TFT and the oxide transistor O-TFT.

In an embodiment, the base layer 110 may be in the form of a single layer. The base layer 110 may include a synthetic resin such as polyimide. The base layer 110 may be formed by coating a synthetic resin layer on the carrier substrate. When the display module DM is completed by performing a subsequent process, the carrier substrate may be removed. In addition, in FIG. 6, a lower film PF coupled with a third adhesive layer AL3 is additionally illustrated under the base layer 110. After the carrier substrate is removed, the lower film PF may be attached to the lower surface of the base layer 110. In this case, the display pads D-PD described in FIG. 2 may be exposed to the outside from the base layer 110. However, the disclosure is not limited thereto, and the base layer 110 may be provided in multiple layers. In an alternative embodiment, for example, a first synthetic resin layer, a second synthetic resin layer, and inorganic layers disposed therebetween may be included in the base layer 110. The display pads D-PD described in FIG. 2 may be exposed to the outside from the first synthetic resin layer disposed at the lowest side.

A barrier layer 10br may be disposed on the base layer 110. The barrier layer 10br prevents foreign substances from entering from the outside. The barrier layer 10br may include at least one inorganic layer. The barrier layer 10br may include a silicon oxide layer and a silicon nitride layer. The silicon oxide layer and the silicon nitride layer may include a plurality of silicon oxide layers and a plurality of silicon nitride layers. The silicon oxide layers and the silicon nitride layers may be alternately stacked one on another.

The first shielding electrode BMLa may be disposed on the barrier layer 10br. The first shielding electrode BMLa may include metal. The first shielding electrode BMLa may include molybdenum (Mo), an alloy containing molybdenum, titanium (Ti), or an alloy containing titanium, which represents a high heat resistance characteristic. The first shielding electrode BMLa may receive a bias voltage. The first shielding electrode BMLa may receive the first power voltage ELVDD. The first shielding electrode BMLa may prevent an electrical potential due to a polarization phenomenon from affecting the silicon transistor S-TFT. The first shielding electrode BMLa may block external light from reaching the silicon transistor S-TFT. According to an embodiment of the disclosure, the first shielding electrode BMLa may be another electrode or a floating electrode isolated from a line.

A buffer layer 10bf may be disposed on the barrier layer 10br to cover the first shielding electrode BMLa. The buffer layer 10bf may prevent metal atoms or impurities from diffusing from the base layer 110 to the upper first semiconductor pattern SC1. The buffer layer 10bf may include at least one inorganic layer. The buffer layer 10bf may include a silicon oxide layer and a silicon nitride layer.

The first semiconductor pattern SC1 may be disposed on the buffer layer 10bf The first semiconductor pattern SC1 may include a silicon semiconductor. In an embodiment, for example, the silicon semiconductor may include amorphous silicon, or polycrystalline silicon. In an embodiment, for example, the first semiconductor pattern SC1 may include lower-temperature polysilicon.

Electrical properties of the first semiconductor pattern SC1 may be different depending on whether the first semiconductor pattern SC1 is doped. The first semiconductor pattern SC1 may include a first region having high conductivity and a second region having low conductivity. The first region may be doped with an N-type dopant or a P-type dopant. The P-type transistor may include a doping region doped with a P-type dopant, and the N-type transistor may include a doping region doped with an N-type dopant. The second region may be a non-doped region or a region doped with a lower concentration than the first region.

The conductivity of the first region may be greater than that of the second region, and the first region may substantially serve as an electrode or a signal line. The second region may substantially correspond to a channel region (or an active region) of the transistor. In other words, a part of the first semiconductor pattern SC1 may be a channel of a transistor, another part may be a source or drain of the transistor, and another part may be a connection electrode or a connection signal line.

The source region SE1, the channel region AC1 (or the active region), and the drain region DE1 of the silicon transistor S-TFT may be formed from the first semiconductor pattern SC1. The source region SE1 and the drain region DE1 may extend from the channel region AC1 in opposite directions, when viewed a cross-sectional view.

A first insulating layer 10 may be disposed on the buffer layer 10bf The first insulating layer 10 may cover the first semiconductor pattern SC1. The first insulating layer 10 may be an inorganic layer. The first insulating layer 10 may be a single-layered silicon oxide layer. The inorganic layer of the circuit layer 120 to be described later as well as the first insulating layer 10 may have a single-layered structure or a multi-layered structure, and may include at least one selected from the above-described materials, but the disclosure is not limited thereto.

A gate GT1 of the silicon transistor S-TFT is disposed on the first insulating layer 10. The gate GT1 may be a portion of the metal pattern. The gate GT1 overlaps the channel region AC1. In the process of doping the first semiconductor pattern SC1, the gate GT1 may be a mask. The first electrode CE10 of the storage capacitor Cst is disposed on the first insulating layer 10. In an alternative embodiment, the first electrode CE10 may have an integral shape with the gate GT1 or be integrally formed with the gate GT1 as a single unitary part.

The second insulating layer 20 may be disposed on the first insulating layer 10 and may cover the gate GT1. Although not illustrated, an upper electrode overlapping the gate GT1 may be disposed on the second insulating layer 20. The second electrode CE20 overlapping the first electrode CE10 may be disposed on the second insulating layer 20.

A second shielding electrode BMLb is disposed on the second insulating layer 20. The second shielding electrode BMLb may be disposed to correspond to a lower portion of the oxide transistor O-TFT. According to an alternative embodiment of the disclosure, the second shielding electrode BMLb may be omitted. According to an embodiment of the disclosure, the first shielding electrode BMLa may extend to the lower portion of the oxide transistor O-TFT to replace the second shielding electrode BMLb.

The third insulating layer 30 may be disposed on the second insulating layer 20. The second semiconductor pattern SC2 may be disposed on the third insulating layer 30. The second semiconductor pattern SC2 may include a channel region AC2 of the oxide transistor O-TFT. The second semiconductor pattern SC2 may include an oxide semiconductor. The second semiconductor pattern SC2 may include a transparent conductive oxide (TCO) such as indium tin oxide (ITO), indium zinc oxide (IZO), indium gallium zinc oxide (IGZO), zinc oxide (ZnOx), or indium oxide (In₂O₃).

The oxide semiconductor may include a plurality of regions divided depending on whether the transparent conductive oxide is reduced. The region in which the transparent conductive oxide is reduced (hereinafter, referred to as a reduction region) has greater conductivity than that of the region in which the transparent conductive oxide is not reduced (hereinafter, referred to as a non-reduction region). The reduction region substantially serves as a source/drain or signal line of the transistor. The non-reduction region substantially corresponds to the semiconductor region (or channel) of the transistor. In other words, a partial region of the second semiconductor pattern SC2 may be a semiconductor region of the transistor, another partial region of the second semiconductor pattern SC2 may be a source region/drain region of the transistor, and still another portion of the second semiconductor pattern SC2 may be a region for transmitting a signal.

The fourth insulating layer 40 may be disposed on the third insulating layer 30. In an embodiment, as illustrated in FIG. 6, the fourth insulating layer 40 may be an insulating pattern overlapping the gate GT2 of the oxide transistor O-TFT and which exposes the source region SE2 and the drain region DE2 of the oxide transistor O-TFT. According to an embodiment of the disclosure, the fourth insulating layer 40 may overlap a plurality of pixels in common to cover the second semiconductor pattern SC2.

The gate GT2 of the oxide transistor O-TFT is disposed on the fourth insulating layer 40. The gate GT2 of the oxide transistor O-TFT may be a portion of the metal pattern. The gate GT2 of the oxide transistor O-TFT overlaps the channel region AC2.

The fifth insulating layer 50 may be disposed on the fourth insulating layer 40, and the fifth insulating layer 50 may cover the gate GT2. Each of the first to fifth insulating layers 10 to 50 may be an inorganic layer.

The first connection electrode CNE1 may be disposed on the fifth insulating layer 50. The first connection electrode CNE1 may be connected to the drain region DE1 of the silicon transistor S-TFT through a contact hole defined or formed through the first to fifth insulating layers 10, 20, 30, 40, and 50.

The sixth insulating layer 60 may be disposed on the fifth insulating layer 50. The second connection electrode CNE2 may be disposed on the sixth insulating layer 60. The second connection electrode CNE2 may be connected to the first connection electrode CNE1 through a contact hole defined or formed through the sixth insulating layer 60. A data line DL may be disposed on the sixth insulating layer 60. The seventh insulating layer 70 may be disposed on the sixth insulating layer 60 to cover the second connection electrode CNE2 and the data line DL. Each of the sixth insulating layer 60 and the seventh insulating layer 70 may be an organic layer.

In the specification, each of the pixel circuits PC may be defined to include “semiconductor patterns” and “conductive patterns”. The “conductive patterns” may include the scan lines SL1 to SLm, the data lines DL1 to DLn, the light emitting lines EL1 to ELm, the first and second control lines CSL1 and CSL2, and the power line PL, and may include the first connection electrode CNE1, the second connection electrode CNE2, the first electrode CE10 and the second electrode CE20 of the capacitor Cst, and the first shield electrode BMLa and the second shield electrode BMLb.

The “semiconductor patterns” may include a gate GT1, a source region SE1, a channel region AC1, and a drain region DE1, which are included in the silicon transistor S-TFT, a gate GT2, a source region SE2, a channel region AC2, and a drain region DE2 which are included in the oxide transistor O-TFT. In addition, the “semiconductor patterns” may be defined as including a gate, a source region, a channel region, and a drain region included in each of transistors necessary to operate the light emitting device LD.

The light emitting device LD may include an anode AE (or a first electrode), a light emitting layer EL, and a cathode CE (or a second electrode). The anode AE of the light emitting device LD may be disposed on the seventh insulating layer 70. The anode AE may be a (semi) light-transmitting electrode or a reflective electrode. The pixel defining layer PDL may be disposed on the seventh insulating layer 70. The pixel defining layer PDL includes a same material and may be formed through the same process. The pixel defining layer PDL may have a property of absorbing light, and for example, the pixel defining layer PDL may have a black color. The pixel defining layer PDL may include a black coloring agent. The black component may include a black dye and a black pigment. The black component may include metal, such as carbon black, or chromium, or an oxide thereof. The pixel defining layer PDL may correspond to a light blocking pattern having a light blocking characteristic.

The pixel defining layer PDL may cover a portion of the anode AE. In an embodiment, for example, an opening part PDL-OP may be defined in the pixel defining layer PDL, to expose a portion of the anode AE.

Although not illustrated, a hole control layer may be disposed between the anode AE and the light emitting layer EL. The hole control layer may include a hole transport layer and may further include a hole injection layer. An electronic control layer may be interposed between the light emitting layer EL and the cathode CE. The electron control layer may include an electron transport layer, and may further include an electron injection layer. The hole control layer and the electronic control layer may be commonly formed in the display region DA (see FIG. 5) using an open mask.

The encapsulation layer 140 may be disposed on the light emitting device layer 130. The encapsulation layer 140 may include an encapsulation inorganic layer 141, an encapsulation organic layer 142, and an encapsulation inorganic layer 143, which are sequentially stacked, but layers constituting the encapsulation layer 140 are not limited thereto.

The encapsulation inorganic layer 141 and the encapsulation inorganic layer 143 may protect the light emitting device layer 130 from moisture and oxygen, and the encapsulation organic layer 142 may protect the light emitting device layer 130 from a foreign substance such as dust particles. The encapsulation inorganic layer 141 and the encapsulation inorganic layer 143 may include a silicon nitride layer, a silicon oxynitride layer, a silicon oxide layer, a titanium oxide layer, or an aluminum oxide layer. The encapsulation organic layer 142 may include, but is not limited to, an acrylic organic layer.

The input sensor ISP may be directly disposed on the display panel DP. The input sensor ISP may include at least one conductive layer and at least one insulating layer. According to an embodiment, the input sensor ISP may include a first sensing insulating layer 210, a first conductive layer 220, a second sensing insulating layer 230, and a second conductive layer 240.

The first sensing insulating layer 210 may be directly disposed on the display panel DP. The first sensing insulating layer 210 may be an inorganic layer including at least one of silicon nitride, silicon oxynitride, and silicon oxide. Each of the first conductive layer 220 and the second conductive layer 240 may have a single-layered structure or a multi-layered structure stacked in the third direction DR3. The first conductive layer 220 and the second conductive layer 240 may include conductive lines defining a mesh-shaped electrode. The conductive line of the first conductive layer 220 and the conductive line of the second conductive layer 240 may be connected to each other or may not be connected to each other through a contact hole defined or formed through the second sensing insulating layer 230. The connection relationship between the conductive line of the first conductive layer 220 and the conductive line of the second conductive layer 240 may be determined depending on the type of sensors constituting the input sensor ISP.

The first conductive layer 220 and the second conductive layer 240 having a single-layered structure may include a metal layer or a transparent conductive layer. The metal layer may include molybdenum (Mo), silver (Ag), titanium (Ti), copper (Cu), aluminum (Al), or an alloy thereof. The transparent conductive layer may include a transparent conductive oxide, such as indium tin oxide (ITO), indium zinc oxide (IZO), zinc oxide (ZnOx), or indium zinc tin oxide (IZTO). In addition, the transparent conductive layer may include a conductive polymer, such as PEDOT, a metal nanowire, or graphene.

The first conductive layer 220 and the second conductive layer 240 having a multiple-layered structure may include a metal layer. The metal layers may, for example, have a three-layer structure of titanium/aluminum/titanium. The conductive layer in the multi-layered structure may include at least one metal layer and at least one transparent conductive layer. The second sensing insulating layer 230 may be interposed between the first conductive layer 220 and the second conductive layer 240.

The anti-reflective layer ARL may be directly disposed on the input sensor ISP. The anti-reflective layer ARL may include a partition layer 310, a color filter 320, and a planarization layer 330.

A material constituting the partition layer 310 is not specifically limited, as long as the material absorbs light. The partition layer 310 has a layer having a black color. According to an embodiment, the partition layer 310 may include a black coloring agent. The black coloring agent may include a black dye, and a black pigment. The black component may include metal, such as carbon black, or chromium, or the oxide thereof.

The partition layer 310 may cover the second conductive layer 240 of the input sensor ISP. The partition layer 310 may prevent reflection of external light by the second conductive layer 240. An opening part 310-OP may be defined in the partition layer 310. The opening part 310-OP may overlap the anode AE. The color filter 320 may overlap the opening part 310-OP. The color filter 320 may make contact with the partition layer 310.

The planarization layer 330 may cover the partition layer 310 and the color filter 320. The planarization layer 330 may include an organic material, and may provide a flat surface on a top surface of the planarization layer 330. According to an alternative embodiment of the disclosure, the planarization layer 330 may be omitted.

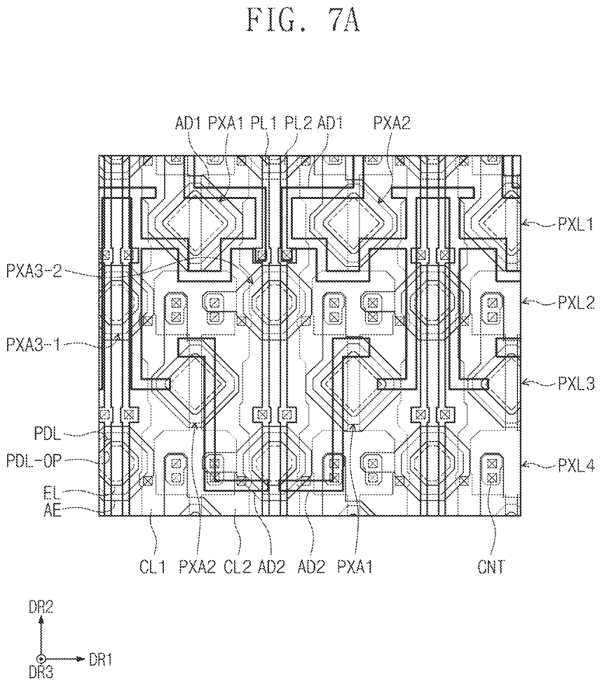

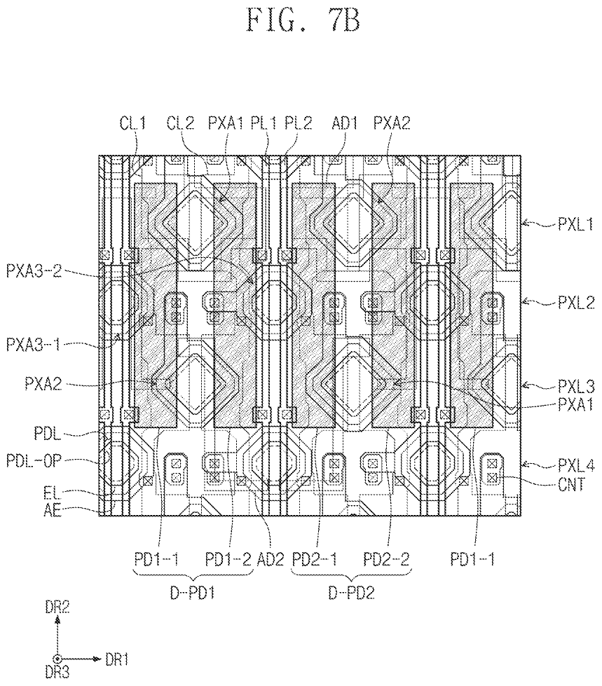

FIG. 7A is a plan view of pixel circuits according to an embodiment of the disclosure. FIG. 7B is a plan view illustrating the arrangement relationship between pixel circuits and pads according to an embodiment of the disclosure.

FIG. 7A illustrates the stack relationship of semiconductor patterns and conductive patterns of pixels PX (see FIG. 5A) disposed in the first to fourth pixel rows PXL1 to PXL4 among the first to sixth pixel rows PXL1 to PXL6, when viewed in a plan view. FIG. 7A illustrates the pixel defining layer PDL, the anode AE exposed through the opening part PDL-OP, and the light emitting layer EL. According to an embodiment, the stack relationship of semiconductor patterns and conductive patterns of pixels PX (see FIG. 5A) when viewed in a plan view may have a mutually-symmetric structure in a specific rule. According to an embodiment, the semiconductor patterns ADL1 and ADL2 and the conductive patterns CL1 and CL2 provided to emit light in the first pixel region PXA1 of the first pixel row PXL1, the a first third pixel region PXA3-1 and the a second third pixel region PXA3-2 of the second pixel row PXL2, and the second pixel region PXA2 of the third pixel row PXL3 may have a symmetric structure to the semiconductor patterns ADL1 and ADL2 and the conductive patterns CL1 and CL2 provided to emit light the second pixel region PXA2 of the first pixel row PXL1, the first third pixel region PXA3-1 and the second third pixel region PXA3-2 of the second pixel row PXL2, and the first pixel region PXA1 of the third pixel row PXL3. The semiconductor patterns AD1 and AD2 and the conductive patterns CL1 and CL2 may be connected to each other through corresponding contact holes CNT.

In an embodiment, the semiconductor patterns AD1 and AD2 may be provided as one pattern, when viewed in a plan view, defining at least a portion of a gate GT1, a source region SE1, a channel region AC1, and a drain region DE1, which are included in a silicon transistor S-TFT, and a gate GT2, a source region SE2, a channel region AC2, and a drain region DE2 which are included in an oxide transistor O-TFT, as illustrated in FIG. 6.

In an embodiment, the “conductive patterns” may be provided as one pattern, when viewed in a plan view, defining at least a portion of the scan lines SL1 to SLm, the data lines DL1 to DLn, the light emitting lines EL1 to ELm, the first and second control lines CSL1 and CSL2, and the power line PL, and the first connection electrode CNE1, the second connection electrode CNE2, the first electrode CE10 and the second electrode CE20 of the capacitor Cst, and the first shield electrode BMLa and the second shield electrode BMLb, as illustrated in FIG. 6.

FIG. 7B illustrates the arrangement relationship between the semiconductor patterns AD1 and AD2, the conductive patterns CL1 and CL2, and the display pads PD1-1, PD1-2, PD2-1, and PD2-2 according to an embodiment of the disclosure, when viewed in a plan view. The display pads PD1-1, PD1-2, PD2-1, and PD2-2 may extend in the second direction DR2 and may be spaced apart from each other in the first direction DR1. The display pads PD1-1, PD1-2, PD2-1, and PD2-2 may have the same area and the same shape as each other, when viewed in a plan view. The display pads PD1-1, PD1-2, PD2-1, and PD2-2 according to an embodiment of the disclosure may overlap the display region DA as described with reference to FIG. 5A.

In an embodiment, as illustrated in FIG. 7B, two pads adjacent to each other in the first direction DR1 are provided in the form of one pad group for the convenience of description. In such an embodiment, the first pad group D-PD1 may include the first first display pad PD1-1 and the second first display pad PD1-2, and the second pad group D-PD2 may include the first second display pad PD2-1 and the second second display pad PD2-2. The description of the first pad group D-PD1 may be identically applied to the description of the second pad group D-PD2.

The display pads PD1-1, PD1-2, PD2-1, and PD2-2 may be exposed to the rear surface DP-B of the base layer 110 shown in FIG. 6 and may be connected to the substrate pads F-PD shown in FIG. 2 in a one-to-one correspondence with each other. The display pads PD1-1, PD1-2, PD2-1, and PD2-2 and the substrate pads F-PD may be bonded to each other through a compression process on the rear surface DP-B of the display panel DP (see FIG. 5A) while interposing an anisotropic conductive film between the display pads PD1-1, PD1-2, PD2-1, and PD2-2 and the substrate pads F-PD.

When the display pads PD1-1, PD1-2, PD2-1, and PD2-2 and the substrate pads F-PD are compressed using a tool bar in a bonding process of compressing the display pads PD1-1, PD1-2, PD2-1, and PD2-2 and the substrate pads F-PD, if a structure to support the display pads PD1-1, PD1-2, PD2-1, and PD2-2 is absent, the pads are pressed without being supported. In this case, the bonding quality between the pads may be degraded due to the step difference.

According to an embodiment of the disclosure, the first first display pad PD1-1 and the second first display pad PD1-2 of the first pad group D-PD1 may have a same overlapping area with the corresponding semiconductor patterns AD1 and AD2 and the corresponding conductive patterns CL1 and CL2, when viewed in a plan view.

In such an embodiment, as the first first display pad PD1-1 and the second first display pad PD1-2 may overlap the relevant (or corresponding) semiconductor patterns AD1 and AD2 and the relevant conductive patterns CL1 and CL2 which are arranged in a specific rule, in the same area, when viewed in a plan view, the first first display pad PD1-1 and the second first display pad PD1-2 may be supported by the semiconductor patterns AD1 and AD2 and the conductive patterns CL1 and CL2, in the same area, when the pads are compressed in the bonding process.

Accordingly, when the pads are pressed on the rear surface DP-B of the display panel DP (see FIG. 5A), the pads may be pressed under the uniform pressure between the adjacent pads PD1-1 and PD1-2. Accordingly, the display device DD (see FIG. 3) may be provided with the improved bonding quality. Any repetitive detailed description of the first second display pad PD2-1 and the second second display pad PD2-2 included in the second pad group D-PD2 will be omitted.

According to an embodiment of the disclosure, as the bonding process is performed with respect to regions of the pads, which overlap the semiconductor patterns AD1 and AD2 and the conductive patterns CL1 and CL2 included in the pixel PX (see FIG. 5A), the semiconductor patterns AD1 and AD2 and the conductive patterns CL1 and CL2 may be damaged in the pressing process. Accordingly, in such an embodiment, the pressure applied to the pads in compressing process using the tool bar is a low pressure in a range of about 1 megapascals (Mpa) to about 6 Mpa, and the pressing process may be performed at the lower pressure in the range of about 1 Mpa to about 6 Mpa.

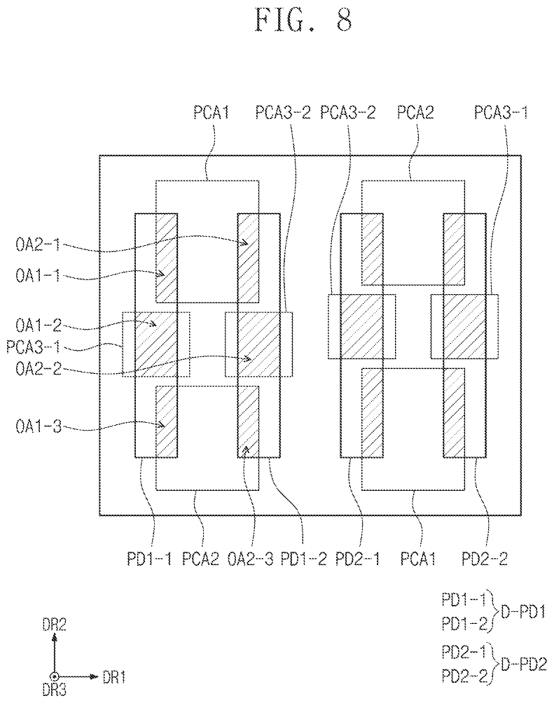

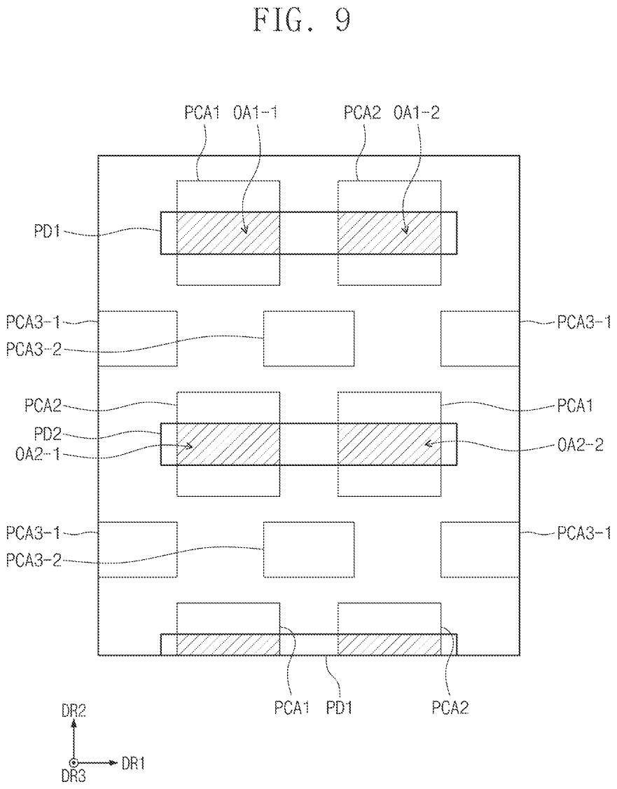

FIG. 8 is a plan view illustrating the arrangement relationship between pixel circuits and pads, according to an embodiment of the disclosure. FIG. 9 is a plan view illustrating the arrangement relationship between pixel circuits and pads, according to an embodiment of the disclosure. FIGS. 8 and 9 briefly illustrate the overlapping relationship between the display pads PD1-1, PD1-2, PD2-1, and PD2-2, the semiconductor patterns AD1, AD2, and the conductive patterns CL1 and CL2, which has been described with reference to FIG. 7B, when viewed in a plan view. In addition, the semiconductor patterns AD1 and AD2 and the conductive patterns CL1 and CL2 described with reference to FIG. 7B are expressed as “pixel circuits”.

Referring to FIG. 8, the first pad group D-PD1 may include the first first display pad PD1-1 and the second first display pad PD1-2, and the second pad group D-PD2 may include the first second display pad PD2-1 and the second second display pad PD2-2.

A portion of the first first display pad PD1-1 may overlap a portion of the first pixel circuit PCA1 that provides the first color light, thereby defining the first first overlapping region OA1-1. A portion of the second first display pad PD1-2 may overlap another portion of the first pixel circuit PCA1, thereby defining the first second overlapping region OA2-1. The first first overlapping region OA1-1 and the first second overlapping region OA2-1 may extend in the second direction DR2, and may be symmetrical to each other about an imaginary axis extending across the space between the first first region OA1-1 and the first second overlapping region OA2-2. Accordingly, the first first overlapping region OA1-1 and the first second overlapping region OA2-1 may have the same area as each other.

Another portion of the first first display pad PD1-1 may overlap a portion of the first third pixel circuit PCA3-1 to provide the third color light, thereby defining the second first overlapping region OA1-2. Another portion of the second first display pad PD1-2 may overlap a portion of the second third pixel circuit PCA3-2 to provide the third color light, thereby defining the second second overlapping region OA2-2. The light emitting device LD (see FIG. 6) connected to the first third pixel circuit PCA3-1 and the light emitting device LD (see FIG. 6) connected to the second third pixel circuit PCA3-2 may generate the same light as each other. Accordingly, the second first overlapping region OA1-2 and the second second overlapping region OA2-2 may have the same area as each other.

A remaining portion of the first first display pad PD1-1 may overlap a portion of the second pixel circuit PCA2 to provide the second color light, thereby defining the third first overlapping region OA1-3. A remaining portion of the second first display pad PD1-2 may overlap another portion of the first pixel circuit PCA2 together with the third second overlapping region OA2-3. The third first overlapping region OA1-3 and the third second overlapping region OA2-3 may extend in the second direction DR2, and may be symmetrical to each other about an imaginary axis extending across the space between the third first overlapping region OA1-3 and the third second overlapping region OA2-3. Accordingly, the third first overlapping region OA1-3 and the third second overlapping region OA2-3 may have the same area as each other. The description of the first pad group D-PD1 may be identically applied to the description of the second pad group D-PD2.

As the first first display pad PD1-1 and the second first display pad PD1-2 overlap the relevant pixel circuits PCA1, PCA2, and PCA3 to have a same overlapping area as each other, the first first pad PD1-1 and the second first display pad PD1-2 may be pressed under the uniform pressure. Accordingly, the display device DD (see FIG. 3) having the improved quality may be provided.

Referring to FIG. 9, each of the display pads PD1 and PD2 may extend in the first direction DR1 and may be spaced apart from each other in the second direction DR2.

A portion of the first display pad PD1 may overlap a portion of the first pixel circuit PCA1 to the first color light, thereby defining the first first overlapping region OA1-1, and a portion of the second pixel circuit PCA2 to provide the second color light different from the first color may overlap a portion of the second pixel circuit PCA2, thereby defining the second first overlapping region OA′-2.

A portion of the display pad PD2 may overlap a portion of the second pixel circuit PCA2 to provide the second color light, thereby defining the first second overlapping region OA2-1, and overlap a portion of the first pixel circuit PCA1, thereby defining the second second overlapping region OA2-2.

According to an embodiment, the first first overlapping region OA1-1 may be symmetrical to the second second overlapping region OA2-2 in a first diagonal direction crossing the first direction DR1 and the second direction DR2. Accordingly, the first first overlapping region OA1-1 and the second second overlapping region OA2-2 may have the same area as each other.

The first first overlapping region OA1-2 may be symmetrical to the first second overlapping region OA2-1 in a second diagonal direction crossing the first direction DR1 and the second direction DR2. Accordingly, the second first overlapping region OA1-2 and the first second overlapping region OA2-1 may have the same area as each other. The second diagonal direction may be perpendicular to the first diagonal direction.

According to an embodiment of the disclosure, the display device may be provided to have a reduced peripheral area, as the circuit board is bonded to the display panel at a region, which overlaps the display region, of the rear surface of the display panel.

In such an embodiment, the display device may be provided with the improved bonding quality in the process of compressing the pad, as the pads adjacent to each other overlap the pixel circuits with a same overlapping area, when viewed in a plan view.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel, in which a display region and a non-display region are defined, wherein the display panel includes a base layer including a front surface and a rear surface opposing the front surface, a circuit layer including pixel circuits disposed on the front surface, wherein each pixel circuit includes semiconductor patterns and conductive patterns, a light emitting device layer including light emitting devices connected to relevant pixel circuits of the pixel circuits, and display pads connected to the relevant pixel circuits and exposed to the rear surface overlapping the display region; and
a circuit board disposed on the rear surface overlapping the display region and including substrate pads connected to the display pads,
wherein a first display pad and a second display pad, which are adjacent to each other, of the display pads overlap relevant semiconductor patterns of the semiconductor patterns and relevant conductive patterns of the conductive patterns with a substantially same overlapping region as each other.

2. The display device of claim 1, wherein regions, in which the first display pad overlaps the pixel circuits, are symmetrical with regions, in which the second display pad overlaps the pixel circuits.

3. The display device of claim 2, wherein a portion of the first display pad overlaps a portion of a first pixel circuit of the pixel circuits, and
wherein a portion of the second display pad overlaps another portion of the first pixel circuit.

4. The display device of claim 3, wherein another portion of the first display pad overlaps a portion of a second pixel circuit of the pixel circuits, and
wherein another portion of the second display pad overlaps a portion of a third pixel circuit of the pixel circuits.

5. The display device of claim 4, wherein the light emitting device connected to the first pixel circuit emits first color light,
wherein the light emitting device connected to the second pixel circuit emits second color light different from the first color light, and
wherein the light emitting device connected to the third pixel circuit emits the second color light.

6. The display device of claim 2, wherein the first display pad and the second display pad extend in a first direction and are spaced apart from each other in a second direction crossing the first direction,
wherein the first display pad overlaps a first pixel circuit and a second pixel circuit, which are spaced apart from each other in the first direction, of the pixel circuits, and
wherein the second display pad overlaps a third pixel circuit, which is spaced apart from the first pixel circuit in the second direction, of the pixel circuits, and a fourth pixel circuit, which is spaced apart from the second pixel circuit in the second direction and is spaced apart from the third pixel circuit in the first direction.

7. The display device of claim 6, wherein the light emitting device connected to the first pixel circuit and the light emitting device connected to the fourth pixel circuit emits first color light, and
wherein the light emitting device connected to the second pixel circuit and the light emitting device connected to the third pixel circuit emits second color light different from the first color light.

8. The display device of claim 1, wherein the first display pad and the second display pad defines a pad group, and
wherein the pad group is provided in plural, and a plurality of pad groups is spaced apart from each other in one direction.

9. The display device of claim 1, wherein the first display pad and the second display pad have a same area as each other.

10. The display device of claim 1, wherein the first display pad and the second display pad have a same shape as each other.

11. The display device of claim 1, wherein the circuit layer includes a plurality of insulating layers, and
wherein the semiconductor patterns and the conductive patterns are interposed between the insulating layers.

12. The display device of claim 1, further comprising:
a lower film interposed between the display panel and the circuit board,
wherein a portion of the circuit board is disposed on a rear surface of the lower film.

13. The display device of claim 1, wherein the display pads and the substrate pads are connected to each other through an anisotropic conductive film.

14. The display device of claim 1, further comprising:
an input sensor directly disposed on the display panel, and including at least one conductive layer and at least one sensing insulating layer.

15. The display device of claim 14, further comprising:
an anti-reflective layer disposed on the input sensor.

16. The display device of claim 15, further comprising:
a window disposed on the anti-reflective layer,
wherein the window includes a base substrate, and a bezel pattern disposed on a bottom surface of the base substrate and overlapping the non-display region.

17. A display device comprising:
a base layer including a front surface, on which a display region and a non-display region are defined, and a rear surface opposing the front surface;
a pixel disposed on the front surface of the base layer, where the pixel includes a pixel circuit including semiconductor patterns and conductive patterns and a light emitting device connected to the pixel circuit;
a display pad connected to the pixel circuit and exposed to the rear surface overlapping the display region; and
a circuit board facing the rear surface overlapping the display region and including substrate pads,
wherein the display pad is provided in plural,
wherein each of the substrate pads is connected to a relevant display pad of display pads,
wherein a first display pad and a second display pad, which are adjacent to each other, of the display pads overlap the pixel circuit with a substantially same overlapping area as each other.

18. The display device of claim 17, wherein the pixel includes:
each of at least one transistor including an active pattern, which is defined by a portion of the semiconductor patterns, and a gate overlapping the active pattern, and
wherein the at least one transistor is connected to the light emitting device.

19. The display device of claim 18, further comprising:
a signal line connected to the pixel and defined by a portion of the conductive patterns,
wherein the signal line includes scan lines, data lines, light emitting lines, control lines, and a power line.

20. The display device of claim 17, wherein regions, in which the first display pad overlaps the pixel circuit, are symmetrical with regions in which the second display pad overlaps the pixel circuit.
